(19) United States
(12) Patent Application Publication
(10) Pub. No.: US 2004/0235281 A1
(43) Pub. Date: Nov. 25, 2004

(54) Apparatus and methods for junction formation using optical illumination

(76) Inventors: Daniel F. Downey, Magnolia, MA (US); Edwin A. Arevalo, Haverhill, MA (US); Reuel B. Liebert, Peabody, MA (US)

Correspondence Address: FOLEY HOAG, LLP, PATENT GROUP, WORLD TRADE CENTER WEST, 155 SEAPORT BLVD, BOSTON, MA, 02110, US

(21) Appl. No.: 10/832,972

(22) Filed: Apr. 26, 2004

Related U.S. Application Data
(60) Provisional application No. 60/465,563, filed on Apr. 25, 2003.

(51) Int. Cl. H01L 21/265

(52) U.S. Cl. 438/530

(57) ABSTRACT

Disclosed are methods and systems that include doping a semiconductor with at least one dopant, and exposing the semiconductor to an optical source(s), where the exposing occurs before, during, and/or after an annealing stage of said semiconductor. The annealing stage can include an annealing phase and/or an activation phase, which can occur substantially simultaneously. The systems can include at least one doping device for providing at least one dopant to a semiconductor, at least one annealing device to perform an annealing stage, and at least one optical source, where the semiconductor is exposed to light from the optical source(s) before, during, and/or after the annealing stage.

### CROSS REFERENCE TO RELATED APPLICATIONS

This Application is related to and claims the benefit of Provisional Application Ser. No. 60/465,563, filed on Apr. 25, 2003, and entitled “Apparatus and Methods for Anneal Optimization in Forming Ultra-Shallow Junctions”.

### BACKGROUND

(1) Field

The disclosed methods and systems relate generally to dopant diffusion and activation control, and more particularly to dopant diffusion and activation control using optical illumination.

(2) Description of Relevant Art

Conventional ion doping systems include ionizing a dopant material such as boron, accelerating the ions to form an ion beam having a given energy level, and directing the ion beam energy at a semiconductor surface or wafer to introduce the dopant material into the semiconductor and alter the conductivity properties of the semiconductor. Once the ions are embedded into the crystalline lattice of the semiconductor, the ions can be activated using several known methods including, for example, rapid thermal annealing (RTA) (a form of rapid thermal process (RTP)). During RTA, the semiconductor can be exposed, for example, to a heat source to rapidly heat the semiconductor to a prescribed temperature and for a prescribed time. RTA, or other forms of annealing, can also cure defects in the crystalline structure that can be caused by the ion implantation. Other methods include furnace annealing, electron beam annealing, laser annealing and exposure to electromagnetic fields such as those in the radio frequency or microwave bands (sometimes referred to as athermal annealing).

The processes of ion implantation and annealing contribute to the depth of the implanted region, known as the junction depth. The depth of the ions from ion doping is based on the energy of the ions doped into the semiconductor and the atomic or molecular weight of doped ions. Shallow doped regions can be formed using low-energy ion beams, and preferably, with an ion dopant having a heavier atomic or molecular weight rather than a lighter weight. Unfortunately, traditional annealing methods which involve raising the temperature of the semiconductor wafer generally cause diffusion of the doped region, and consequently an increase in the junction depth over the as-implanted dopant distribution.

The increase in junction depth can be particularly troublesome when considered with respect to a continuing and expanding demand for smaller devices, and hence shallower junction depths.

### SUMMARY

Disclosed are methods and systems that include doping a semiconductor with a dopant(s), and exposing the semiconductor to an optical source(s), where the exposing occurs before, during, and/or after an annealing stage of the semiconductor. The annealing stage can include an annealing phase and/or an activation phase, which can occur substantially simultaneously. Further, the exposing can occur during a portion, or more, of the annealing stage, and the exposing can include varying a wavelength of the optical source with the exposure.

In one embodiment, the semiconductor can be exposed to a first optical wavelength during a first part of the annealing stage, and, exposed to a second (or more) optical wavelength during a second (or more) part of the annealing stage. Accordingly, the exposing can occur during a portion of a temperature increase and/or a temperature decrease. The optical source(s) can include a laser(s), a laser diode(s), and/or a lamp(s), and in some embodiments, can include a variable wavelength optical source. A variable wavelength optical source can include a first wavelength range(s) that may be used for the exposing, and a second wavelength range(s) that may be used for the annealing stage. In an embodiment where the optical source(s) may include a lamp illuminating light having a plurality of wavelength ranges, the lamp can be coupled to an optical filter for selecting one or more of a plurality of wavelength ranges.

In some embodiments, the optical source(s) provides light having a wavelength range substantially between approximately 200 nanometers and approximately 1100 nanometers, while in some embodiments, the optical source(s) provides light having a wavelength range substantially between approximately 300 nanometers and approximately 800 nanometers. Further, the annealing can be performed by the optical source(s).

In some of the disclosed methods and systems, a semiconductor can include a plurality of semiconductor regions, such that exposing includes directing light produced by the optical source(s) onto one or more of the plurality of regions. Directing the light can include translating the semiconductor relative to the optical source(s), which may be performed by placing the semiconductor on a movable platform such as an X-Y table. In some embodiments, directing the light can include translating the optical source(s) relative to the semiconductor, including, for example, varying the orientation of the optical source(s) relative to the semiconductor. In an embodiment, directing the light can include scanning the optical source(s) across at least a part of the surface of the semiconductor using a method known to those skilled in the art.

Based on the optical source, the optical source(s) may produce an illumination having a controlled shape, such that exposing the semiconductor can include scanning the semiconductor with the illumination having the controlled shape. The controlled shape may be a line or a rectangle. The exposing can also include controlling an incident angle between the optical source(s) and the semiconductor.

For some embodiments of the disclosed methods and systems, the annealing stage can be performed by a heat source(s), the semiconductor can include a plurality of semiconductor regions, and, the annealing can include directing radiation generated by the heat source(s) onto at least one of the plurality of semiconductor regions. The heat source(s) can include a laser(s), a laser diode(s), and/or a lamp(s).

As with the optical device, the semiconductor can be translated relative to the heat source(s), and/or vice-versa, using a movable table such as an X-Y device, and/or the heat source(s) can be scanned (electronically, mechanically, or otherwise) across at least a part of the surface using a controlled pattern, such as, for example, a line or a rectangle.

The disclosed methods and systems can include determining a wavelength based on properties of the semiconductor and properties of the dopant(s), and selecting the optical source(s) such that the optical source(s) provides the determined wavelength. Properties of the semiconductor can include a chemical composition of the semiconductor, while properties of the dopant(s) may include a chemical composition of the dopant(s).

In some embodiments, the annealing can include heating the semiconductor to a first temperature, and, heating the semiconductor to a second temperature, where the second temperature is greater than the first temperature. It can thus be understood that the annealing stage in the disclosed methods and systems can include at least one of a Rapid Thermal Annealing (RTA), Solid Phase Epitaxy (SPE), and/or Flash Rapid Thermal Annealing, although such examples are provided for illustration and not limitation. It can also be understood that during the annealing stage the disclosed methods and systems include exposing the semiconductor to a temperature in a temperature range substantially between approximately 500° C. and approximately 1400° C., and that such exposing is performed for a time period substantially between approximately one nanosecond and approximately ninety minutes. Additionally, it can also be understood that in the disclosed methods and systems the annealing stage includes using an electromagnetic field(s), a laser(s), a laser diode(s), a lamp(s), a hot gas(es), a furnace(s), a hot plate(s), a rapid thermal annealer(s), carbon radiative heater(s), and/or quartz-halogen lamp(s).

In some embodiments, the dopant(s) can include one or more ionic species that may include a halogen(s), for example, one or more of Boron, Fluorine, Germanium, Silicon, Phosphorus, and Arsenic. The doping can further be performed by beam-line implantation, plasma doping (PLAD), pulsed plasma doping (P²LAD), preamorphized implantation, and/or doped deposited layer.

In an embodiment, the doping can include controlling oxygen content based on the dopant, where the oxygen content can be substantially between approximately one part per million and approximately one-thousand parts per million.

Also disclosed is a system in accordance with the disclosed methods, where the system includes a doping device(s) for providing at least one dopant to a semiconductor, an annealing device(s) to perform an annealing stage, and an optical source(s), where the semiconductor is exposed to light from the optical source(s) before, during, and/or after the annealing stage. As provided herein, the annealing device(s) and the optical source(s) may be the same device, and may include a laser(s), a laser diode(s), and/or a lamp(s) which can be coupled to an optical filter(s) for selecting one or more of a plurality of wavelength ranges.

Other objects and advantages will become apparent hereinafter in view of the specification and drawings.

### BRIEF DESCRIPTION OF THE DRAWINGS

FIG. 1 is one embodiment of a system and method for performing optical illuminated annealing;

FIG. 2 is a plot of the dopant concentration versus junction depth at different O₂ concentrations using laser illuminated microwave spike annealing;

FIG. 3 is a plot of BF₂ dopant concentration versus junction depth using three different types of annealing processes;

FIG. 4 is a plot showing the dopant concentrations versus junction depth for two types of dopants using a spike anneal process;

FIG. 5 is a plot showing the dopant concentrations versus junction depth for two types of dopants using a laser illuminated microwave spike anneal process;

FIG. 6 is a plot showing the dopant concentrations versus junction depth for two types of dopants using a flash anneal process; and

FIG. 7 is a plot of BF₂ dopant concentration versus junction depth for three different wavelength illuminations.

### DESCRIPTION

To provide an overall understanding, certain illustrative embodiments will now be described; however, it will be understood by one of ordinary skill in the art that the systems and methods described herein can be adapted and modified to provide systems and methods for other suitable applications and that other additions and modifications can be made without departing from the scope of the systems and methods described herein.

Unless otherwise specified, the illustrated embodiments can be understood as providing exemplary features of varying detail of certain embodiments, and therefore features, components, modules, and/or aspects of the illustrations or processes can be otherwise combined, separated, interchanged, and/or rearranged without departing from the disclosed systems or methods.

Traditional methods for the manufacture of semiconductor wafer involve doping the wafer with dopant ions, followed by an annealing stage process. During ion doping, the doped regions can be damaged when the accelerated, energized dopant ions collide with the host, referred to here as an exemplary silicon surface, displacing silicon atoms from their original lattice sites. Although the dopant ions can be in high-energy non-equilibrium positions in the silicon lattice, the dopant ions are not electrically active. An annealing process can provide energy to the silicon and dopant ions to allow movement of the ions to equilibrium positions, thereby also repairing the doping damage by restoring crystallographic order. During this process the dopant ions are electrically activated to alter the conductivity of the substrate. Unfortunately, some annealing techniques, such as rapid thermal annealing (RTA), that expose the semiconductor to high temperatures in the range of 500-1400 degrees Celsius, often cause dopant redistribution or diffusion. Although certain types of RTA, including spike anneal, impulse anneal, flash assist anneal, and/or laser anneal, may under certain circumstances and with respect to different wafers and/or dopants, achieve acceptable activation rates and reduced dopant diffusion depth profiles, RTA, as well as other types of annealing techniques, can nevertheless, for certain dopant doses, increase junction depths to be significantly deeper than, for example, the as-implanted range.

The disclosed methods and systems expose a semiconductor to the output of an optical source (referred to herein as “exposed to an optical source”), where such exposure can occur before, during, and/or after an annealing stage process. The annealing stage, which can include an annealing phase during which the semiconductor wafer is heated and crystal damage is cured, and an activation phase during which the dopants become active and render the formed junction operational, can be obtained by exposure to a variety of energy sources. The annealing phase and activation phase of the annealing stage can occur sequentially or simultaneously, by the same and/or different techniques and/or methods/apparatus. The optical illumination can be combined with control chemistry to optimize multi-charged carrier and/or exciton complexes which are shown to increase activation and the interstitial complexes can be relatively immobile (see U.S. Ser. No. 09/835,653 filed on Apr. 16, 2001, and U.S. Ser. No. 10/142,313 filed on May 9, 2002, both of which are incorporated herein by reference in their entirety). The disclosed methods and systems can further be combined with other techniques for creating ultra-shallow junctions, including, for example, controlling oxygen content, and/or doping another ionic species to facilitate activation and/or decrease dopant diffusion.

The disclosed methods and systems can also include doping a semiconductor wafer with a dopant and an ionic species simultaneously, and/or consecutively where the order of doping can vary based on application. The doping process can include an ion implantation process such as beam-line implantation, plasma doping (PLAD), or pulsed plasma doping (P²LAD), although the disclosed methods and systems are not limited to such doping techniques. Methods including preamorphization or preamorphized implantation (PAI), among other methods, as well as doped deposit layer techniques (e.g., in situ doping), can also be used in the doping process or method. In the illustrated systems, the selected dopant may be Boron (B⁺), while the ionic species may be Fluorine (F⁻). The disclosed processes include utilizing the ions and/or molecules based on the ionic species during doping to produce an ionic species-rich environment during doping and during the particular annealing regime, where the annealing can follow the single or multi-stage doping. In one embodiment, the ionic species-rich environment can be provided via ion doping of molecular combinations of the dopant and the ionic species. For example, ion doping can be used to implant BF₂ to a semiconductor for forming a junction. In another example, the ionic species-rich environment can be accomplished via PLAD. For example, when Boron (B⁺) is the dopant and Fluorine (F⁻) is the ionic species, PLAD can be performed using a BF₃ source.

As provided herein, the doping process can be followed by one of several known annealing processes, including annealing by microwave and/or radio frequency (RF) annealing, although other thermal and athermal annealing methods can be used. As is understood, athermal annealing generally refers to annealing methods in which very little energy in the infrared electromagnetic spectrum is transferred to the wafer. One example of athermal annealing is electromagnetic induction heating (EMIH). Methods and systems for such an example of athermal annealing are disclosed in U.S. patent application Ser. No. 10/115,211 entitled “Dopant Diffusion and Activation Control with Athermal Annealing”, and in U.S. patent application Ser. No. 09/996,446 entitled “Athermal Annealing with Rapid Thermal Annealing System and Method”, the contents of both of which are hereby incorporated by reference in their entirety. EMIH can be understood as a unique application of Faraday's and Ampere's laws. As a silicon wafer is exposed to electromagnetic fields, electrons are induced to flow within the wafer. As the electrons collide with the lattice, they release energy that heats the silicon wafer. Alternatively, traditional RTA techniques such as spike annealing, flash assist annealing, etc. may be used instead and/or in addition to athermal annealing. Further, annealing of the wafer may be performed using scanning techniques, methods and systems, such as those described in U.S. patent application Ser. No. 10/325,497 entitled “Thermal Flux Processing by Scanning”, the contents of which is hereby incorporated by reference in its entirety. As is understood, such scanning techniques and methods may include directing radiation (e.g., electromagnetic) across selected areas on the surface of a wafer. Directing the radiation can be performed, for example, by causing the radiation beam to move across the wafer's surface through translation of the position of the electromagnetic source (e.g., a laser) relative to the wafer, and/or translation of the radiation beam by employing directing apparatus such as, for example, lenses, mirrors, waveguides, etc., or otherwise controlling the radiation beam to cause it to scan the surface of the wafer. Alternatively, scanning techniques may be implemented, for examples, by displacing the wafer relative to the radiation source and/or radiation beam, using, for example, translation apparatus such as an X-Y table and/or other translation apparatus and equipment known to a person skilled in the art.

Although the examples provided herein include using silicon as a semiconductor, those of ordinary skill in the art will recognize that other well-known semiconductors including the Group IV elements or compounds of Group III and Group V materials can be used in addition to, or in place of, silicon. The examples provided herein also include utilizing Boron as the selected dopant; however, Aluminum, Gallium, Indium, Phosphorus, Arsenic, and Antimony, or another p-type or n-type dopant can be used in addition to or in place of Boron (B+). Further, the examples provided herein include an ionic species illustration of Fluorine, but other ionic species can be used, including but not limited to Group 17 halogens and/or halides (Fluorine, Chlorine, Bromine, Iodine, and Astatine) or other ionic species or reactive intermediates derived from Group 17, or another Group can optionally and additionally be used without departing from the scope of the disclosed processes.

As provided herein, the disclosed optical exposure methods and systems can also include controlling low level oxygen ambients during annealing, where such oxygen control methods are described in U.S. Pat. No. 6,087,247 to Downey entitled “Method for Forming Shallow Junctions in Semiconductor Wafers Using Controlled Low Level Oxygen Ambients during Annealing”, the contents of which are herein incorporated by reference in their entirety. As provided in the aforementioned patent, during annealing, oxygen concentration can be controlled at or near a selected level in a range less than approximately 1000 parts per million. For example, oxygen concentration level can be in a range substantially between approximately and approximately 1000 parts per million. The oxygen control can be determined based on the selected dopant and/or the ionic species. Oxygen control can be based on a desired concentration versus junction depth profile. The oxygen concentration can be controlled by reducing the oxygen below a desired level by purging or vacuum pumping the chamber in which the annealing stage is performed, and introducing a controlled amount of oxygen. In an embodiment, the chamber can be backfilled with a gas that includes oxygen at or near the selected oxygen concentration level. Other gas control techniques can also be used to create the desired oxygen concentration in the annealing chamber.

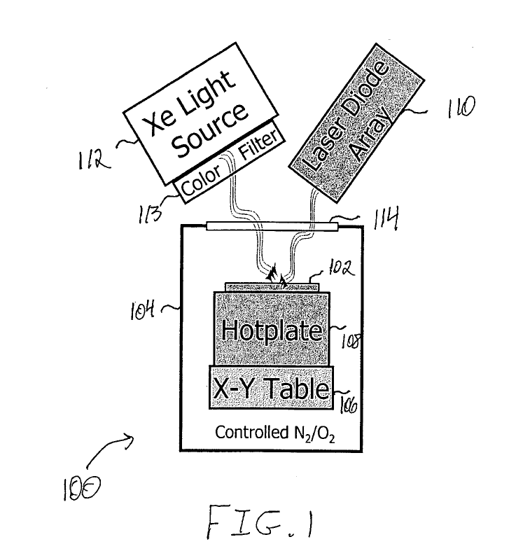

FIG. 1 shows an exemplary embodiment of an illuminated annealing system 100. Such an illuminated annealing system may perform any one of the known annealing regimes, such as spike annealing, flash annealing, Solid Phase Epitaxy (SPE) annealing, thermal scanning, etc., by using the various modules/components comprising system 100 to control the temperature, exposure time, and/or exposure pattern to which wafer 102 is subjected. Further, optical illuminated annealing may be performed by athermal annealing, using, for example, a microwave source, or other sources of electromagnetic radiation. As shown, semiconductor wafer 102 is placed on a hotplate 108 which rests on a surface such as, for example, X-Y table 106. X-Y table 106 may be used to enable translation of wafer 102 relative to the heating and illuminating sources described herein, and thereby provide a mechanism for applying heat generated by the heating sources onto selected areas of wafer 102, and/or provide a mechanism for exposing light provided by an optical source to selected areas of wafer 102. X-Y table 106 may be any commercially available X-Y table, including X-Y tables manufactured, for example by Aim Controls Inc., and may include a motorized translation mechanism (not shown) and/or a control module for controlling the motion of the movable surface of the X-Y table (also not shown). Alternatively, wafer 102 and/or hotplate 108 may rest on a stationary platform or surface.

Wafer 102, as well as hotplate 108 and surface 106 are enclosed inside annealing chamber 104. Annealing chamber 104 may be substantially sealed and impervious to any gaseous or non-gaseous particles and pollutants outside of chamber 104, thereby preventing the entry of such pollutants into annealing chamber 104. A vacuum pump (not shown) and a gas injecting apparatus (not shown) may be coupled to annealing chamber 104 to provide a mechanism for controlling the ambient conditions inside annealing chamber 104, such as, for example, the 02 content inside the chamber 104. Particularly, such a vacuum pump and gas injector may be used to introduce into chamber 104 desired gases, such as N₂ (and/or other inert gases), and O₂. The desired O₂ concentration in N₂ (and/or other gases in chamber 104) can subsequently be controlled using the vacuum pump.

Also shown in FIG. 1 is a secondary heat source such as a laser or laser diode array optical system 110 that may (but does not have to) be used to provide energy to heat wafer 102. Laser system 110 may be a commercially available laser diode array such as, for example, those manufactured by Laser Diode Array, Inc. As would be understood by the person versed in the art, hotplate 108 may be used to heat wafer 102 to a first intermediate temperature, while laser diode array 110 may be used to provide the energy to heat wafer 102 to a second, higher, temperature. It would be appreciated that other heat sources for heating the wafer 102 to the intermediate temperature may be used, including thermal heat sources such as carbon radiative heater, furnace injection equipment, quartz-halogen lamps, lasers, lamps, etc., as well as heat sources such as microwave heat sources, radio frequency heat sources, etc. Likewise, other heat sources for heating wafer 102 to its second temperature may be used, including a laser, flash lamp, microwave source, and all other heat sources for performing wafer annealing that are known to a person skilled in the art. Alternatively, only one heat source, such as a hotplate, laser, microwave generator, lamp, etc., may be used to heat the wafer to the temperature required for performing and completing the annealing process. As described herein, the energy sources that are applied to the wafer for one or all of the heat sources may be applied to substantially the entire wafer 102 by using, for example, a hotplate to heat the wafer, and/or scanned across the wafer using the X-Y table 106 to move wafer 102 relative to the heating source. Other annealing methods known in the art, including those described by C. Hill in Chapter 13 of “Laser Annealing of Semiconductors”, edited by J. M. Poate and James W. Mayer, the contents of which are hereby incorporated by reference in its entirety, may also be used.

As can be seen in FIG. 1, since laser diode array 110 is placed outside annealing chamber 104, a plate 114 may be used to allow energy produced by laser diode array 110, and/or another heat source for facilitating the annealing stage process, to enter chamber 104, while isolating the interior of chamber 104 from the ambient conditions and pollutants outside the chamber. In the embodiment described herein, plate 114 may be transparent, thereby allowing light produced by an optical heating source such as array 110 to enter chamber 104. Otherwise, plate 114 may be translucent, thus allowing light having particular wavelength(s) to enter chamber 104, or it may be opaque and allow other forms of radiation, such as microwave radiation, to enter chamber 104. Alternatively, a secondary heating source may be coupled directly to chamber 104, thereby obviating the need for plate 114, or other barriers for insulating the interior of chamber 104 from the outside.

As can also be seen in FIG. 1, disposed above annealing chamber 104, and wafer 102, is optical source 112, which in the exemplary embodiment described herein may by a Xenon light source, such as the Model 66926 Xenon Continuous Light Source, manufactured by Spectra-Physics. An optical light source such as the 66926 Xenon Light Source can produce light having, for example, a substantial portion of its spectral output in the range of 200-1100 nanometer, and an average output power of, for example, 1000 W. The wavelength region desired may be chosen by use of an optical filter, such as a color or interference filter, and the exposure time controlled by use of an electronic or mechanical shutter. Other optical sources may be used with system 100, including lamps using other gases, a laser apparatus, such as those manufactured by Spectra Physics, laser diode (or laser diode array), pulsed lamps, and/or other optical sources known to a person skilled in the art. Optical systems which control the shape of the exposed region of the wafer can be used according to the choice of scanning technique chosen or may be designed to illuminate the entire wafer uniformly. Such other optical sources used with system 100 may have different spectral outputs, and different power levels. For example, in some embodiments the optical source may produce optical illumination in the wavelength range substantially between approximately 200 nanometers and approximately 1100 nanometers. In other embodiments described herein, the optical range of optical illumination generated by an optical source such as optical source 112, can be between approximately 300 nanometers and 800 nanometers.

To obtain substantially monochromatic light from an optical source 112 such as a lamp, an optical filter may be coupled to the lamp 112 to permit light with specific wavelengths to enter cavity 104. Thus, as shown in FIG. 1, coupled to the output of optical source 112 is an optical filter 113 that enables selection of illumination having particular wavelength(s) from amongst the spectral output produced by optical source 112. Filter 113 may be an adjustable filter such as a monochromator, thus allowing optical source 112 to effectively be a variable wavelength optical source. Illumination generated by the optical source 112 and filtered by filter 113 enters annealing chamber 104 via plate 114, whereupon the illumination is directed onto wafer 102 to promote reduced dopant diffusion and/or increased dopant activation in the manner described herein.

It will be appreciated that more than one optical source may be included with system 100, and/or the other systems described herein, and that each such optical source may illuminate at a different wavelength(s) and during different periods of the annealing stage process. Thus, one optical source may, for example, illuminate wafer 102 at the same time that wafer 102 is being heated, while another optical source (or the same) may be activated during the time the wafer 102 is being cooled. Further, where an additional optical source is used, that additional optical source may illuminate at a wavelength that is different than the wavelength of the illumination produced by the first optical source. Alternatively, a single variable wavelength optical source capable of illuminating at different wavelengths may be used with system 100, and/or with the other systems described herein. Accordingly, optical source 112 may illuminate wafer 102 while the wafer is being heated, but may be deactivated while the wafer 102 is being cooled down, or otherwise illuminate wafer 102 with a different wavelength illumination.

While shown suspended above annealing chamber 104, it will be appreciated that optical source 112 may be positioned inside annealing chamber 104, for example, and be attached to one of the walls of chamber 104, thereby foregoing the need to have the light enter the chamber through an interfacing mechanism such as plate 114. Further, it will be appreciated that optical source 112 may be positioned in other orientations relative to wafer 102, either on the inside or outside of chamber 104. By positioning the optical source 112 in different orientations, the illuminated light may be directed to different areas of the surface of the wafer, thus providing a mechanism whereby the geometry of the dopant diffusion within the wafer can be controlled. Particularly, as described herein, the light illuminated on the wafer's surface can reduce the extent of the dopant diffusion and/or increase the extent of dopant activation within the wafer. By directing the illumination from the optical source 112 to specific areas of the wafer's surface, the extent of dopant diffusion and/or dopant activation in specific regions can thus be controlled. Additionally, by controlling the orientation of the optical source 112 (e.g., a lamp and filter, a laser, a laser diode, etc.), the illumination can be directed onto the surface of the wafer to provide horizontal diffusion of a dopant. Further, different orientations of optical source 112 may also cause the incident angle of the illumination relative to the surface of wafer 102 to vary, thereby providing another mechanism for controlling the amount of dopant diffusion and/or activation in wafer 102. It will be appreciated that illumination from optical source 112 may also be directed to selected regions/areas of wafer 102 by translating the wafer 102 relative to optical source 112 through translation of X-Y table 106. In other words, optical source 112 may remain stationary, while wafer 102 may be spatially translated relative to optical source 112 such that different regions/areas on wafer 102 may become exposed to the illumination emanating from optical source 112.

For the illustrated system of FIG. 1 temperature measurements can be provided by collecting radiated light using an optical pyrometer or light pipe. The collected radiated light can be analyzed by, for example, a Luxtron model analyzer that matches the collected light intensities to a black body radiation spectrum to produce a temperature of the silicon wafer. In some embodiments, the spectrum may be modified or scaled to provide an accurate temperature measurement based on the emissivity of silicon. It is understood that any of the many other forms of optical pyrometry known to those skilled in the art can be used as alternatives to the Luxtron technology.

In operation, wafer 102 is placed on hotplate 108 which begins to heat the wafer to a first temperature corresponding to the intermediate temperature of the particular annealing regime being implemented (e.g., a flash annealing regime may have a different intermediate temperature than the intermediate temperature for a spike annealing regime). A doping procedure such as P²LAD for placing dopant ions, such as Boron (B), on the wafer may also be performed, although, as would be appreciated by a person skilled in the art, such a doping procedure may have been completed prior to the commencement of the annealing stage process. The optical source 112 may have previously activated the dopant in the wafer, and may have begun illuminating the wafer through plate 114 prior to the commencement of the annealing stage process. Alternatively, illumination from optical source 112 may be applied to wafer at some later stage (e.g., during the annealing stage process, or at the completion of the annealing stage). Further, the level of O₂ in the annealing chamber may also be adjusted to O₂ levels that promote reduced dopant diffusion, and/or increased dopant activation. When wafer 102 is heated its target intermediate temperature, heat generated by a secondary heat source, such as, for example a laser diode array, may be applied to wafer 102, thereby increasing the temperature of wafer 102 to a temperature that enables completion of the annealing stage process. At a specified time, which may depend, among other things, on the particular nature of the wafer materials, the annealing regime implemented, etc., the heating of wafer 102 by the secondary heat source may be suspended, thereby allowing the wafer to cool.

The annealing performed on the semiconductor may be athermal annealing, such as electromagnetic induction heating, performed, for example, using a microwave generator. Alternatively, the annealing performed on wafer 102 may be thermal annealing, such as spike annealing, flash assist annealing, and/or another Rapid Thermal Annealing (RTA) technique, performed using a thermal heating source, such as a hot plate, carbon radiative heater, furnace injection equipment, quartz-halogen lamps, laser(s), a laser diode array(s), lamps, and other thermal heating sources known in the art. Further, as described herein, in situations where the annealing technique is based on the use of an optical source, and the same optical source is used to also provide the illumination for reducing dopant diffusion and/or increasing dopant activation, the optical source can be one that illuminates at a wavelength(s) that, for the particular semiconductor and dopant used, provides reduced diffusion and higher activation rates than other wavelength(s). Additionally, annealing of wafer 102 may also be performed using scanning techniques whereby heat from the first and or second heating source(s) may be directed to selected regions of the wafer's surface by translating wafer 102 relative to the heating sources, and/or translating the heating source and/or varying the heating sources' orientations relative to the wafer, and/or directing the radiation produced by the heating source to selected areas of the wafer. Such scanning techniques and methods may facilitate controlling the junction's geometry in wafer 102.

In addition, the geometry of the dopant diffusion in semiconductor wafer 102 can be also controlled by spatially orienting optical source 112 with respect to semiconductor wafer 102, and/or fitting optical source 112 with beam focusing devices, so that illumination from optical source 112 onto semiconductor wafer 102 can be directed to selected regions of wafer 112. Consequently, by directing the illumination from optical source 112 onto selected regions/areas of wafer 102, the illumination so directed may promote reduced dopant diffusion and/or increased dopant activation in those regions, but not necessarily in other regions/areas of the wafer. Beam focusing devices that may be used to direct the illumination from optical source 112 onto specific regions/areas of wafer 102 may include optical lenses for focusing light, and/or all other types of optical focusing devices known to a person skilled in the art. Furthermore, wafer 102 may be displaced relative to optical source 102, and/or other optical sources used to reduce dopant diffusion and/or dopant activation in wafer 102, by controlling the translation of X-Y table 106 relative to such optical sources. Additionally, the geometry of the optical source and/or annealing sources may also be controlled to produce shapes which are compatible with one of the known scanning sources in the state of the art. For example, a line-shaped and/or rectangular-shaped light source scanned across the wafer could be used to uniformly expose the wafer to very short duration pulses of light without producing seams between exposed areas.

Those with ordinary skill in the art will recognize that the exemplary annealing systems of FIG. 1 is merely illustrative and the implementation thereof is not limited to the embodiments or characteristics provided herein. For example, in some embodiments spike annealing processes may be used in which the semiconductor wafer 102 is subjected to temperatures in a range substantially between approximately 750° C. to approximately 1400° C., for a period of between one-tenth (0.1) of one second and approximately two (2) seconds. In other embodiments, the spike annealing processes can include temperatures substantially between approximately 950° C. and approximately 1100° C., with the exposure of the semiconductor wafer to temperature in that range also being for a time period substantially between approximately one-tenth (0.1) of one second and approximately two (2) seconds. In such embodiments in which spike annealing is used, the heat to perform the spike annealing can be provided by heat sources generating and releasing hot gases, equipment for the generating and releasing microwave energy, firnaces, optical sources (e.g., a lamp, laser, etc.), hot plates, graphite strip heaters, standard quartz halogen heaters, and/or other heat generating sources.

In other embodiments, flash annealing may be performed in which the wafer may be subjected to temperatures in the range substantially between approximately 500° C. and approximately 1400° C., for a period of between approximately one nanosecond to approximately one second. In such embodiments in which flash annealing is used, the heat to perform flash annealing can be provided by microwave energy, or heat-producing optical sources (e.g., a lamp or laser exposing the wafer to optical illumination having particular wavelengths bands), and/or other heat sources/generators. For example, flash annealing may be performed using the FRTA system manufactured by Vortek Industries. Such systems use a lamp to heat the wafer to an intermediate temperature, and subsequently discharge a flash of power, produced by the lamp, thereby causing the wafer to experience a sharp rise in surface and interior temperature.

Additionally, in some further embodiments, Solid Phase Epitaxy (SPE) annealing may be performed. In some embodiments employing SPE annealing, a furnace, a hot plate, or some other thermal annealer, may be used to provide the heat applied to the wafer. In such embodiments the wafer may be subjected to temperatures in the range substantially between approximately 500° C. to approximately 750° C., for a period of between approximately one-tenth (0.1) of one second to approximately 10 minutes. In other embodiments employing SPE annealing, a microwave source or an optical source, such as lamp or a laser, may be used to provide the heat that is applied to the wafer. In those embodiments, the wafer may be subjected to temperatures in the range substantially between approximately 500° C. to approximately 100° C., for a period substantially between approximately one (1) second to approximately sixty (60) seconds.

In those embodiments herein described, including, for example, those embodiments in which spike annealing, flash annealing, and/or Solid Phase Epitaxy annealing are performed, such embodiments may use at least one optical illumination source, such as a laser illuminating light, or a lamp, such as a Xenon light source, coupled to a filter, in a manner similar to system 100 of FIG. 1; however, in embodiments in which the heating source is an optical source, it may not be necessary to include an additional optical source to provide the illumination for improving the junction-forming performance results. For example, the fRTA Vortek system uses a lamp to heat the wafer. Such a lamp can be used in the dual capacity of heating the wafer to perform annealing, and illuminating the wafer to promote improved junction-forming results (e.g., decreased diffusion, increased activation). Nevertheless, in some other embodiments in which heating is provided by an optical source, a second optical source, and/or additional optical sources, may be used to provide additional illumination to promote improved junction-formation results. For example, one optical source can produce light at wavelengths that may assist in and/or otherwise facilitate annealing, while a second optical source may be used to illuminate the wafer using other wavelengths that may promote improved junction-forming. For example, in a Mattson 3000 Plus RTA system that uses a lamp to perform an RTA anneal, the spectral distribution of the light produced by the lamp can be inappropriate for producing non-annealing optical illumination as provided herein, and thus a second optical source for illuminating the wafer to improve junction-forming performance results may be used.

As previously noted, a semiconductor wafer may first be heated to an intermediate temperature using a heating source, such as for example, a hot plate, and subsequently the same or another heating source, for example, a laser diode, may be used to raise the temperature of the wafer to a temperature required for annealing the wafer. For example, as would be recognized by those skilled in the art, flash assist annealing involves heating a wafer to a first (e.g., “intermediate”) temperature, and then applying a flash of heat to the wafer, thereby raising the wafer's temperature to a second, higher, temperature.

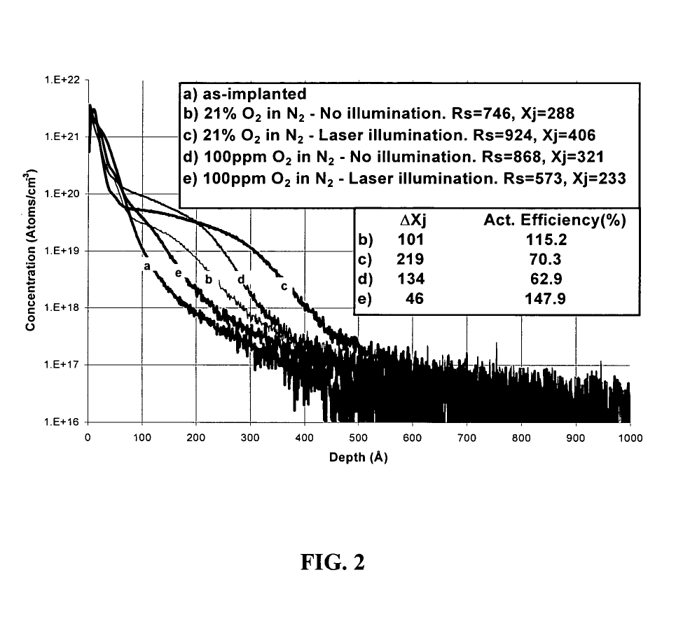

The effect of optical illumination on the junction-forming process in terms of the dopant activation and diffusion rates is shown in the Secondary Ion Mass Spectrometry (SIMS) overlays presented in FIGS. 2-6. The SIMS overlays of FIGS. 2-6 were analyzed using a Physical Electronics 6600 Quadrupole SIMS instrument with a 1.0 KeV O₂ beam at a 60° incident angle. FIGS. 2-6 show the dopant concentration versus depth in the silicon substrate, and provide additional measured or computed values helpful in determining the efficacy of using an optical source to illuminate the wafer to improve junction-forming performances. These values include:

1) Sheet resistance Rₛ, measured by either a KLA-Tencor Rs-100, or Rs-35;

2) Junction Depth Xⱼ;

3) ΔXj, computed as the difference between the depth of dopant distribution in the wafer after the dopant implanting process is completed (sometimes referred to as the “as-impanted” junction depth), and the junction depth after the annealing stage has been completed.

4) Activation Efficiency, computed as:

$$Activation Efficiency ( {R}_{s} ) := \frac{{R}_{s}^{total}}{{R}_{s}} \cdot 100 \% \qquad ( 1 )$$

in which Rₛ^{total} is calculated as:

$$\frac{1}{{R}_{s}^{total}} = {\sum }_{i = 1}^{n} \frac{1}{{R}_{i}} = {\sum }_{i = 1}^{n} \frac{1}{{ρ}_{i}} {d}_{i} , \qquad ( 2 )$$

where dᵢ is an individual wafer layer thickness with resistivity ρᵢ. The resistivity ρ corresponding to a particular layer in the wafer is computed based on the empirical relation:

$$ρ = \frac{1.305 \cdot {10}^{16}}{{C}_{B}} + \frac{1.133 \cdot {10}^{17}}{{C}_{B} [ 1 + {( 2.58 \cdot {10}^{- 19} \cdot {C}_{B} )}^{- 0.737} ]} \qquad ( 3 )$$

where C_{B} is the Boron concentration in the corresponding layer.

The resistivity ρ for a particular layer is computed on the assumption that all the dopant atoms in the wafer have been activated. Accordingly, the activation efficiency is expressed as a ratio between the actual measured resistivity of the wafer and the theoretical resistivity, assuming all the implanted dopant atoms have been activated. It is to be noted that the activation efficiency may result in values higher than 100% due to inaccuracies of the SIMS profiles. Nevertheless, although the activation efficiency values are susceptible to measurement errors, these values are considered to be more reliable than calculating sheet resistivity values which, like the activation efficiency values, are derived from the SIMS profiles, but which, in contrast to the activation efficiency values, do not account for the theoretical sheet resistivity of the wafer.

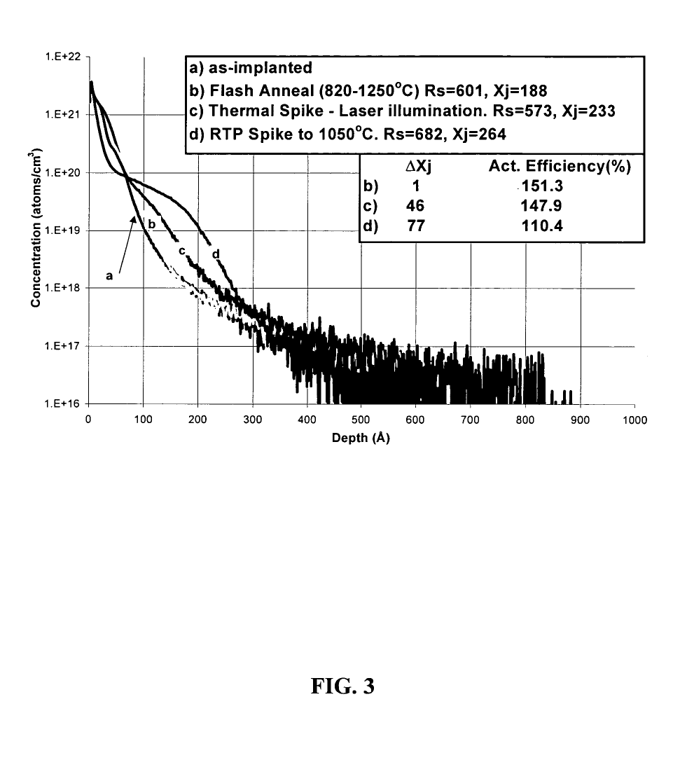

FIG. 2 shows the effect of laser illumination on junction-forming performances in the presence of two different O₂ ambient concentrations. More particularly, the dopant concentration versus depth profiles were determined for O₂ concentrations of 21%, in N₂, and 100 parts per million (ppm) of O₂ in N₂, with and without laser illumination. The samples tested for determining the effect of optical illumination as presented in FIG. 2, and as presented in FIGS. 3-6, were 3 cm by 1.5 cm Silicon wafers. In the experiments pertaining to the results shown in FIGS. 2-6, dopants were implanted at a 0° tilt angle using either a Varian VIISion-80 ULE, Varian VIISta-80, or Varian VIISTta 10 P²LAD system using a BF₃ plasma source. Other doping implanting techniques and/or different doping implanting apparatus may be used instead. In studying the effects of optical illumination, the samples were implanted with a 2.2 keV, 1e15/cm² BF₂, and were then pre-heated for 30 seconds at 550° C. using microwave radiation, before being athermally spike annealed, also by microwave radiation, to 1050° C. In the microwave radiation experiments conducted in relation to FIG. 2, the microwave source generating the 2.45 GHz annealing microwave radiation did not produce infrared, optical, or ultra-violet illumination, and accordingly, the only source of light illumination came from the optical source used. In the particular system used for obtaining the results shown in FIG. 2, the optical source used was a collimated laser producing a laser beam having a 672 nanometer wavelength and generating 100 mW power. Typical power densities were approximately 15-50 mW/cm². The optical illumination was then focused on each of the wafer samples used for these measurements such that half of each sample was illuminated while the other half remained dark. The laser was activated during the 550° C. pre-heat, and remained activated for the high temperature treatment. An advantage of this experimental arrangement is that both the illuminated and the non-illuminated parts of the samples received an identical thermal treatment, such that optical illumination was the only variable.

As indicated by FIG. 2, use of optical illumination on the wafers resulted in an improvement in the activation efficiency (70.3% to 147.9%), and of the ΔXj values (219 Å compared to 46 Å) when the ambient oxygen concentration was changed from 21% of O₂ in N₂ to 100 ppm of O₂ in N₂. By contrast, when laser illumination was not directed at the wafer samples, the activation efficiency and ΔXj values calculated for the wafer sample became worse when the ambient concentration of O₂ was changed from 21% O₂ in N₂ to 100 ppm O₂ in N₂, the activation efficiency having decreased from 115.2% to 62.9%, and the ΔXj value having increased from 101 Å to 134 Å.

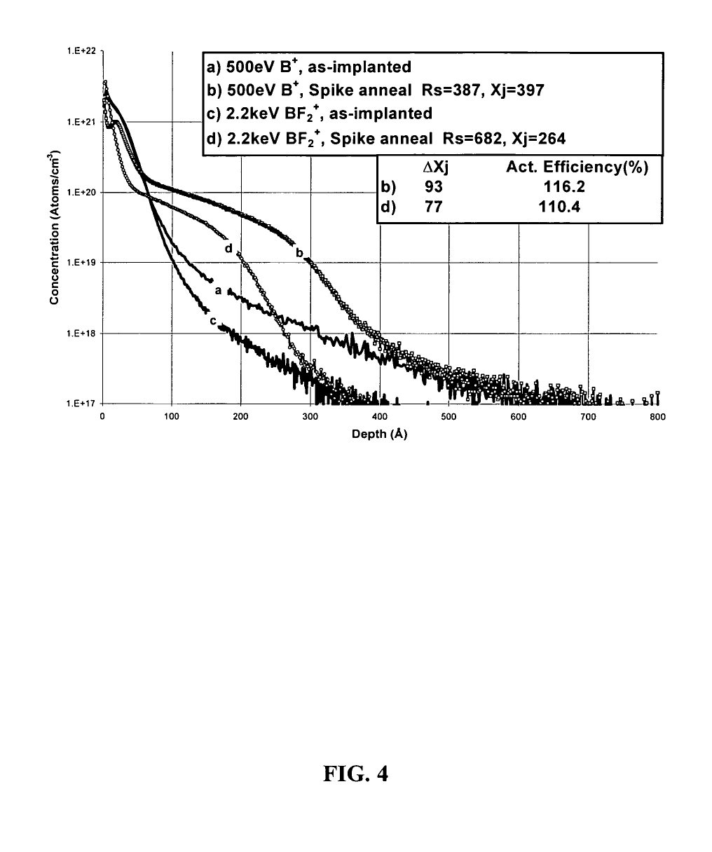

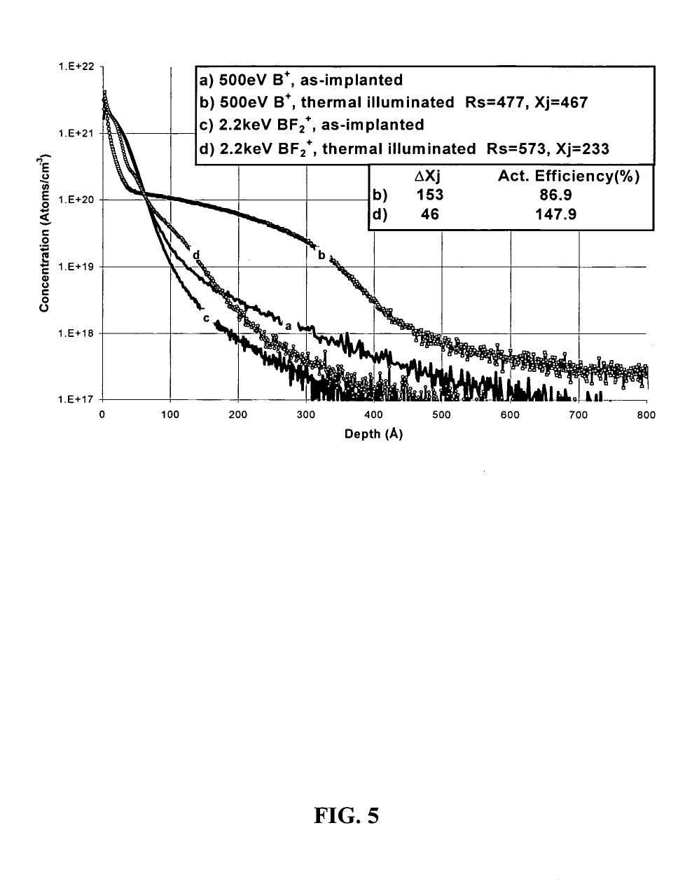

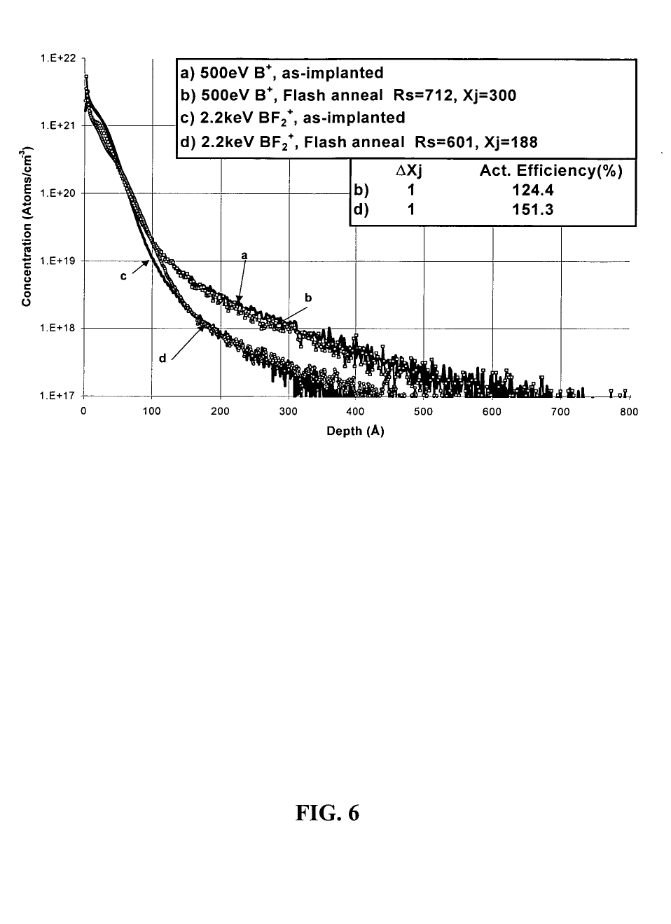

FIG. 3 shows the junction-forming performance results for laser illuminated microwave spike anneal in an ambient concentration of 100 ppm O₂ in N₂, as compared to other types of anneals performed under similar conditions. More particularly, FIG. 3 shows SIMS overlays of an as-implanted 2.2 keV, 1e15/cm² BF₂ implant (curve (a) in FIG. 3), an RTA spike anneal at 1050° C. (curve (d) in FIG. 3), a “flash” RTA anneal that peaked from 820° C. to 1250° C. for about 1.2 ms, and thereafter cooled to 820° C. (curve (b) in FIG. 3), and the laser-illuminated sample (curve (c) in FIG. 3). For the RTA spike anneals performed in the experiments pertaining to FIG. 3 (and also those pertaining to FIG. 4), a Mattson 3000 Plus RTA system was used. For the flash assist RTA anneals performed in the experiments pertaining to FIG. 3 (and also those pertaining to FIG. 6), an fRTA Vortek Industries system was used. As was previously noted, for the illuminated microwave spike anneal process performed in relation to FIG. 3 (as well as those performed in relation to FIGS. 2, and 5), a microwave furnace was used.

As FIG. 3 indicates, the laser illuminated sample had a lower diffusion than the samples subjected to RTA spike anneals (46 Å as compared to 77 Å), and also had a higher activation efficiency (147.9% as compared to 110.4%). The “flash” RTA sample, on the other hand, had negligible diffusion, with an activation efficiency of 151.7%. The RTA spike anneal and the “flash” RTA anneal both had diffusion values approximately matching the values predicted by thermal diffusion theory. The laser-illuminated sample, however, diffused less than predicted by thermal diffusion theory.

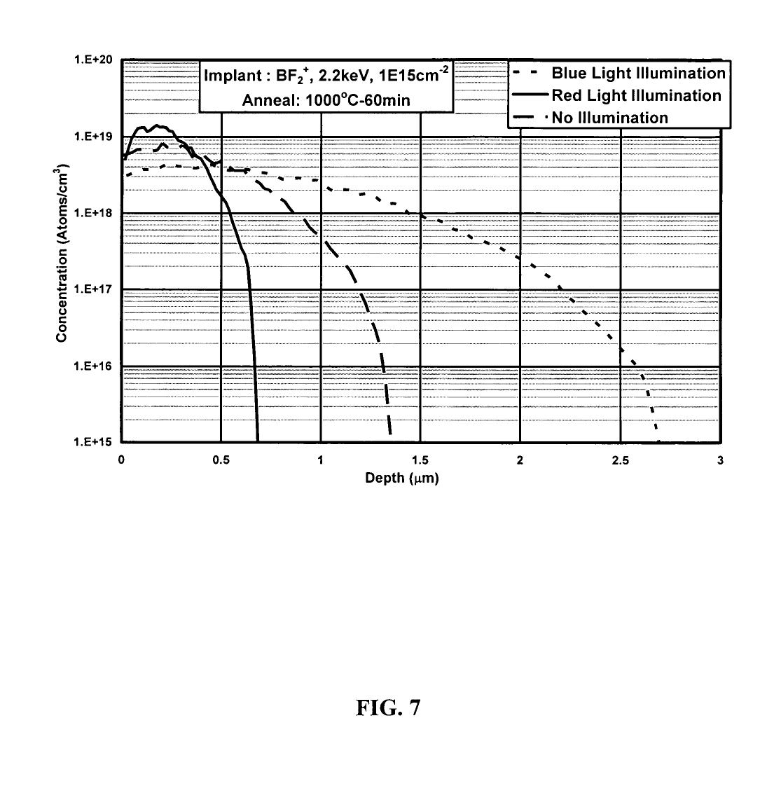

It is to be noted that the fRTA Vortek Industries systems, with which the flashing annealing process was performed and which uses a lamp in which 45% of the emitted light components had wavelengths of less than 672 nanometers, showed better junction-forming results than the RTA spike anneal procedure, which was performed using a lamp in which the emitted light had a spectral distribution where less than 10% of the optical components had wavelengths below 672 nanometers. Further, FIG. 7 shows a graph comparing the effect optical illumination at different wavelengths on the junction-formation performance results when the dopant used was BF₂ and an optical illuminated microwave spike annealing process was performed at a temperature of 1000° C. for sixty minutes. As can be seen, for the particular dopant used, and at the specified temperature, illumination with a wavelength of 560 nanometers (corresponding to the solid line curve in FIG. 7) resulted in shallower junctions than those resulted for illuminations having wavelengths of 320 nanometers (corresponding to the dashed line curve), and when no illumination was used (corresponding to the broken line curve). As can also be seen from FIG. 7, using illumination with a wavelength of 320 nanometers resulted in an increased junction depth as compared to the junction depth that resulted when no illumination was used in the annealing stage. FIG. 7 thus suggests that for given combinations of semiconductor materials, dopants, anneal temperatures, anneal durations, and ambient conditions (such as the oxygen content in the annealing chamber), different illumination wavelengths can provide different junction-forming performance results.

Accordingly, optimization of the annealing process can involve the determination of an illumination wavelength to be used. Further, with respect to the flash assist annealing and the spike anneal process compared in FIG. 3, the superior junction-forming performance results obtained using the flash assist annealing process as compared to the spike anneal process may be indicative of the fact that for Silicon semiconductor doped with BF₂ dopant, shorter wavelength illumination may promote better junction-forming performance results (as noted, 45% of the illumination constituents in the flash assist annealing process had wavelength shorter than 672 nanometers, compared to only 10% of the illumination constituents in the spike anneal process).

The three annealing regimes compared in FIG. 3 were subsequently each applied to wafer samples doped with one of Boron (B⁺) and BF₂⁺ dopants. FIG. 4 shows SIMS overlays of RTA spike anneals at 1050° C. in 100 ppm O₂ in N₂ ambient. As can be seen, the diffusion of the BF₂ dopant was reduced in comparison to the B dopant (77 Å compared to 93 Å), although the activation efficiency was higher for the B dopant (116.2% vs. 110.4%).

As can be seen in FIG. 5, showing the dopant concentration versus junction depth for two types of dopants with and without the application of a laser illuminated microwave spike anneal process, the effects of the use Fluorine become more pronounced when the spike annealed wafers (heated by microwave radiation) were illuminated with an optical source, such as a laser, that was activated during the anneal. As shown in FIG. 5, the junction formed in the samples in which BF₂⁺ was used was much shallower than the sample using the B⁺ dopant, diffusing only 46 Å as compared to 153 Å. Additionally, the activation efficiency was much higher for the BF₂⁺ sample (147.9%) than for the B+ sample (86.9%).

FIG. 6 shows the effects of flash RTA on a 500 eV 1e15/cm² B and on a 1e15/cm² 2.2 keV BF₂ dopant. In the experiments conducted in relation to FIG. 6, the flash was peaked from 820° C. to 1250° C. and then cooled to 820° C. using a 1.2 millisecond pulse. As FIG. 6 illustrates, using flash RPT annealing resulted in almost no diffusion of the dopant ions (i.e., for both the B+ and the BF₂⁺ dopant, the flash RTA process yielded ΔXj values of 1); however, the BF₂⁺ sample had a higher activation efficiency of 151.3% as compared to 124.4% for the B⁺ sample.

FIGS. 2-6 thus indicate that use of optical illumination in the annealing process can contribute to shallower junction depths and improved activation efficiencies. Particularly, whether optical illumination is inherent in the annealing process itself (as it is in the Vortek fRTA system which uses lamps to perform flash assist annealing), or whether an independent additional optical source is added to the annealing system, the junction-forming performance results are improved in that the activation efficiency increases and the junction depth of semiconductor wafers decreases.

What has thus been described are methods and systems that include doping a semiconductor with at least one dopant, and exposing the semiconductor to an optical source(s), where the exposing occurs before, during, and/or after an annealing stage of said semiconductor. The annealing stage can include an annealing phase and/or an activation phase, which can occur substantially simultaneously. The systems can include at least one doping device for providing at least one dopant to a semiconductor, at least one annealing device to perform an annealing stage, and at least one optical source, where the semiconductor is exposed to light from the optical source(s) before, during, and/or after the annealing stage.

The methods and systems described herein are not limited to a particular hardware or software configuration, and may find applicability in many computing or processing environments. The methods and systems can be implemented in hardware or software, or a combination of hardware and software. The methods and systems can be implemented in one or more computer programs executing on one or more programmable computers that include a processor, a storage medium readable by the processor (including volatile and non-volatile memory and/or storage elements), one or more input devices, and one or more output devices.

Unless otherwise stated, use of the word “substantially” can be construed to include a precise relationship, condition, arrangement, orientation, and/or other characteristic, and deviations thereof as understood by one of ordinary skill in the art, to the extent that such deviations do not materially affect the disclosed methods and systems.

Throughout the entirety of the present disclosure, use of the articles “a” or “an” to modify a noun can be understood to be used for convenience and to include one, or more than one of the modified noun, unless otherwise specifically stated.

Elements, components, modules, and/or parts thereof that are described and/or otherwise portrayed through the figures to communicate with, be associated with, and/or be based on, something else, can be understood to so communicate, be associated with, and or be based on in a direct and/or indirect manner, unless otherwise stipulated herein.

Although the methods and systems have been described relative to a specific embodiment thereof, they are not so limited. Obviously many modifications and variations may become apparent in light of the above teachings. For example, as previously provided herein, although the figures illustrated the use of Boron (B⁺) as a selected p-type dopant with a Fluorine (F⁻) as the selected ionic species, the methods and systems can be applied to other p-type and n-type dopants, as well as other ionic species. The illustrated embodiments may include an oxygen-controlled annealing chamber at oxygen levels of, for example, 100 parts per million, although those with ordinary skill in the art will recognize that the controlled oxygen amount can vary based on the dopant, and can range, for example, between 1 and 1000 parts per million, for example.

Many additional changes in the details, materials, and arrangement of parts, herein described and illustrated, can be made by those skilled in the art. Accordingly, it will be understood that the following claims are not to be limited to the embodiments disclosed herein, can include practices otherwise than specifically described, and are to be interpreted as broadly as allowed under the law.

What is claimed is:

1. A method comprising:
doping a semiconductor with at least one dopant, and
exposing said semiconductor to at least one optical source, where the exposing occurs at least one of: before, during, and after an annealing stage of said semiconductor.

2. A method according to claim 1, where the annealing stage includes at least one of: an annealing phase and an activation phase.

3. A method according to claim 2, where the annealing phase and the activation phase occur substantially simultaneously.

4. A method according to claim 1, where the exposing occurs during at least a portion of the annealing stage.

5. A method according to claim 1, where exposing further comprises varying a wavelength with the exposure.

6. A method according to claim 1, where exposing further comprises:
exposing the semiconductor to a first optical wavelength during a first part of the annealing stage, and,
exposing the semiconductor to at least one second optical wavelength during at least one second part of the annealing stage.

7. A method according to claim 1, where the exposing occurs during a portion of at least one of: a temperature increase and a temperature decrease.

8. A method according to claim 1, where said at least one optical source comprises at least one: of a laser, a laser diode, and a lamp.

9. A method according to claim 1, where the at least one optical source includes a variable wavelength optical source.

10. A method according to claim 9, where the variable wavelength optical source includes at least one first wavelength range for the exposing, and at least one second wavelength range for the annealing stage.

11. A method according to claim 1, where said at least one optical source comprises a lamp illuminating light having a plurality of wavelength ranges, said lamp coupled to an optical filter for selecting at least one of said plurality of wavelength ranges.

12. A method according to claim 1, where said at least one optical source provides light having a wavelength range substantially between approximately 200 nanometers and approximately 1100 nanometers.

13. A method according to claim 1, where said at least one optical source provides light having a wavelength range substantially between approximately 300 nanometers and approximately 800 nanometers.

14. A method according to claim 1, where said annealing is performed by said at least one optical source.

15. A method according to claim 1, where said semiconductor comprises a plurality of semiconductor regions, and where exposing comprises directing light produced by said at least one optical source onto at least one of said plurality of regions.

16. A method according to claim 15, where directing comprises translating said semiconductor relative to said at least one optical source.

17. A method according to claim 16, where said semiconductor is placed on a movable platform, and where said translating is performed by said movable platform.

18. A method according to claim 17, where said movable platform comprises an X-Y table.

19. A method according to claim 15, where directing comprises translating said at least one optical source relative to said semiconductor.

20. A method according to claim 15, where directing comprises varying the orientation of said at least one optical source relative to said semiconductor.

21. A method according to claim 15, where directing comprises scanning said at least one optical source across at least a part of the surface of said semiconductor.

22. A method according to claim 1, where said at least one optical source produces light having a controlled shape, and where exposing comprises scanning said semiconductor with said illumination having said controlled shape.

23. A method according to claim 22, where said controlled shape includes at least one of: a line, and a rectangle.

24. A method according to claim 1, where exposing comprises controlling an incident angle between said at least one optical source and said semiconductor.

25. A method according to claim 1, where:
said annealing stage is performed by at least one heat source,
said semiconductor comprises a plurality of semiconductor regions, and,
said annealing comprises directing radiation generated by said at least one heat source onto at least one of said plurality of semiconductor regions.

26. A method according to claim 25, where said at least one heat source includes at least one of: a laser, a laser diode, and a lamp.

27. A method according to claim 25, where directing comprises translating said semiconductor relative to said at least one heat source.

28. A method according to claim 27, where said semiconductor is placed on a movable platform, and where said translating is performed by said movable platform.

29. A method according to claim 28, where said movable platform comprises an X-Y table.

30. A method according to claim 25, where directing comprises translating said at least one heat source relative to said semiconductor.

31. A method according to claim 25, where directing comprises varying the orientation of said at least one heat source relative to said semiconductor.

32. A method according to claim 25, where said at least one heat source produces radiation having a controlled shape, and where exposing comprises scanning said semiconductor with said radiation having said controlled shape.

33. A method according to claim 32, where said controlled shape includes at least one of a line, and a rectangle.

34. A method according to claim 25, where exposing comprises controlling an incident angle between said at least one heat source and said semiconductor.

35. A method according to claim 25, where directing comprises scanning said at least one heat source across at least a part of the surface of said semiconductor.

36. A method according to claim 1, further comprising determining a wavelength based on properties of said semiconductor and on properties of said at least one dopant, and selecting said at least one optical source such that said at least one optical source provides said determined wavelength.

37. A method according to claim 36, where said properties of said semiconductor include a chemical composition of said semiconductor.

38. A method according to claim 36, where said properties of said at least one dopant include a chemical composition of said at least one dopant.

39. A method according to claim 1, where said annealing comprises:
heating said semiconductor to a first temperature, and,
heating said semiconductor to a second temperature, said second temperature being greater than said first temperature.

40. A method according to claim 1, where said annealing stage comprises performing at least one of: a Rapid Thermal Annealing (RTA), Solid Phase Epitaxy (SPE), and Flash Rapid Thermal Annealing.

41. A method according to claim 1, where said annealing stage comprises subjecting said semiconductor to a temperature in a temperature range substantially between approximately 500° C. and approximately 1400° C.

42. A method according to claim 41, where subjecting is performed for a time period substantially between approximately one nanosecond and approximately ninety minutes.

43. A method according to claim 1, where said annealing stage comprises using at least one of: an electromagnetic field, a laser, a laser diode, a lamp, at least one hot gas, a furnace, a hot plate, a rapid thermal annealer, carbon radiative heater, and a quartz-halogen lamp.

44. A method according to claim 1, where the at least one dopant includes at least one ionic species.

45. A method according to claim 44, where said ionic species includes a halogen.

46. A method according to claim 45, where said ionic species includes ions of at least one of: Boron, Fluorine, Germanium, Silicon, Phosphorus, and Arsenic.

47. A method according to claim 1, where doping includes at least one of: beam-line implantation, plasma doping (PLAD), pulsed plasma doping (P²LAD), preamorphized implantation, and doped deposited layer.

48. A method according to claim 1, where doping includes controlling oxygen content based on the dopant.

49. A method according to claim 1, where doping includes controlling oxygen content substantially between approximately one part per million and approximately one-thousand parts per million.

50. A system, comprising:
at least one doping device for providing at least one dopant to a semiconductor,
at least one annealing device to perform an annealing stage, and
at least one optical source,
where said semiconductor is exposed to light from said at least one optical source at least one of:
before, during, and after the annealing stage.

51. A system according to claim 50, where said at least one optical source comprises at least one of: a laser, a laser diode, and a lamp.

52. A system according to claim 50, where said at least one optical source comprises a lamp illuminating light having a plurality of wavelength ranges, said lamp coupled to an optical filter for selecting at least one of said plurality of wavelength ranges.

53. A system according to claim 50, where said at least one optical source provides light having a wavelength range substantially between approximately 200 nanometers and approximately 1100 nanometers.

54. A system according to claim 50, where said at least one optical source provides light having a wavelength range substantially between approximately 300 nanometers and approximately 800 nanometers.

55. A system according to claim 50, where said at least one annealing device is said at least one optical source.

56. A system according to claim 50, where said semiconductor comprises a plurality of semiconductor regions, and where said at least one optical source directs light onto at least one of said plurality of regions.

57. A system according to claim 56, where said semiconductor is translated relative to said at least one optical source.

58. A system according to claim 57, where said semiconductor is placed on a movable platform, and where said translating is performed by said movable platform.

59. A system according to claim 58, where said movable platform comprises an X-Y table.

60. A system according to claim 56, where the orientation of said at least one optical source is varied relative to said semiconductor.

61. A system according to claim 50, where said at least one optical source is scanned across at least a part of the surface of said semiconductor.

62. A system according to claim 50, where said semiconductor is scanned with said light having a controlled shape.

63. A system according to claim 62, where said controlled shape includes at least one of: a line, and a rectangle.

64. A system according to claim 50, further comprising an optical controller for controlling an incident angle between said at least one optical source and said semiconductor.

65. A system according to claim 50, where said semiconductor comprises a plurality of semiconductor regions, and where said at least one annealing device directs radiation generated by said at least one annealing device onto at least one of said plurality of semiconductor regions.

66. A system according to claim 65, where said at least one annealing device includes at least one of: a laser, a laser diode, and a lamp.

67. A system according to claim 65, where said semiconductor is translated relative to said at least one annealing device.

68. A system according to claim 67, where said semiconductor is placed on a movable platform, and where said translating is performed by said movable platform.

69. A system according to claim 68, where said movable platform comprises an X-Y table.

70. A system according to claim 65, where said at least one annealing device is translated relative to said semiconductor.

71. A system according to claim 65, where the orientation of said at least one annealing device is varied relative to said semiconductor.

72. A system according to claim 65, where said semiconductor is scanned with radiation having a controlled shape.

73. A system according to claim 72, where said controlled shape includes at least one of: a line, and a rectangle.

74. A system according to claim 65, further comprising an annealing device controller for controlling an incident angle between said at least one annealing device and said semiconductor.

75. A system according to claim 65, where said at least one optical source scans across at least a part of the surface of said semiconductor.

76. A system according to claim 50, where said at least one optical source produces a wavelength based on properties of said semiconductor and properties of said at least one dopant.

77. A system according to claim 76, where said properties of said semiconductor include a chemical composition of said semiconductor.

78. A system according to claim 76, where said properties of said at least one dopant include a chemical composition of said dopant.

79. A system according to claim 50, where said at least one annealing device heats semiconductor to a first temperature, and heats said semiconductor to a second temperature, said second temperature being greater than said first temperature.

80. A system according to claim 50, where said at least one annealing device performs at least one of: Rapid Thermal Annealing (RTA), Solid Phase Epitaxy (SPE), and Flash Rapid Thermal Annealing.

81. A system according to claim 50, where said at least one annealing device exposes said semiconductor to a temperature in a temperature range substantially between approximately 500° C. and approximately 1400° C.

82. A system according to claim 81, where said semiconductor is subjected to said temperature for a time period substantially between approximately one nanosecond and approximately ninety minutes.

83. A system according to claim 50, where said at least one annealing device includes at least one of: an electromagnetic field, a laser, a laser diode, a lamp, at least one hot gas, a furnace, a hot plate, a rapid thermal annealer, carbon radiative heater, and a quartz-halogen lamp.

84. A system according to claim 50, where the at least one doping device includes at least one device capable of: beam-line implantation, plasma doping (PLAD), pulsed plasma doping (P²LAD), preamorphized implantation, and doped deposit layer.

85. A system according to claim 50, where said at least one dopant includes at least one ionic species.

86. A system according to claim 85, where said at least one ionic species includes a halogen.

87. A system according to claim 86, where said at least one ionic species includes ions of at least one of: Boron, Fluorine, Germanium, Silicon, Phosphorus, and Arsenic.

88. A system according to claim 50, further comprising an oxygen level controller for controlling oxygen content in said system based on the dopant.

89. A system according to claim 50, further comprising an oxygen level controller for controlling oxygen content in said system to be substantially between approximately one part per million and approximately one-thousand parts per million.

90. A system according to claim 50, where the annealing stage includes at least one of an anneal phase and an activation phase.

91. A system according to claim 90, where the anneal phase and the activation phase occur substantially simultaneously.

92. A system according to claim 50, where said semiconductor is exposed to light from said at least one optical source during at least a portion of the annealing stage.

93. A system according to claim 50, where said at least one optical source includes a variable wavelength optical source.

94. A system according to claim 50, where said semiconductor is exposed to light having a first optical wavelength during a first part of the annealing stage, and to at least one second optical wavelength during at least one second part of the annealing stage.

95. A system according to claim 50, where the said semiconductor is exposed to light during a portion of at least one of: a temperature increase, and a temperature decrease.
